(19) United States
(12) Patent Application Publication
(10) Pub. No.: US 2019/0150305 A1
(43) Pub. Date: May 16, 2019

(54) ACCOMMODATION BOX AND ELECTRONIC COMPONENT UNIT

(71) Applicant: Yazaki Corporation, Tokyo (JP)

(72) Inventors: Masayuki NAOHARA, Shizuoka (JP); Tomohiro SUGIURA, Shizuoka (JP); Yoshihiro KAWAMURA, Shizuoka (JP)

(73) Assignee: Yazaki Corporation, Tokyo (JP)

(21) Appl. No.: 16/168,229

(22) Filed: Oct. 23, 2018

(30) Foreign Application Priority Data
Nov. 16, 2017 (JP) 2017-220796

(51) Int. Cl. H05K 5/02; H05K 5/03

(52) U.S. Cl. CPC H05K 5/0204; H05K 5/03; H05K 5/0239; H05K 5/0221

(57) ABSTRACT

An accommodating member includes a cylindrical body. The cylindrical body has a double-wall structure, which includes an inner wall body and an outer wall body. The outer wall body includes: a protruding wall portion protruding toward the insertion port side than the inner wall body; and at least one protruding body protruding from an inner wall surface of the protruding wall portion within a range of a size of the gap. The double-wall structure has a space, which extends in the cylinder-axis direction in a state of providing the gap and has only both ends in the cylinder-axis direction opened, between the inner wall body and the outer wall body. The space includes: a first opening on the insertion port side and a second opening on the closing wall body side which are arranged to oppose the protruding body.

### CROSS-REFERENCE TO RELATED APPLICATION(S)

The present application claims priority to and incorporates by reference the entire contents of Japanese Patent Application No. 2017-220796 filed in Japan on Nov. 16, 2017.

### BACKGROUND OF THE INVENTION

### 1. Field of the Invention

The present invention relates to an accommodation box and an electronic component unit.

### 2. Description of the Related Art

Conventionally, for example, one having an electronic component or the like as an accommodation target is known as an accommodation box. The accommodation box includes a box-shaped accommodating member in which an accommodation target is accommodated. For example, the accommodating member includes: a cylindrical body having an inner space that serves as an accommodation chamber of an accommodation target; a closing wall body that closes one of both ends in a cylinder-axis direction of the cylindrical body; and an insertion port of the accommodation target which is open at the other end. Such a type of accommodation box is disclosed, for example, in the following Japanese Patent Application Laid-open No. 2017-22184 and No. 2017-22809.

Here, there is an accommodating member in which a protruding body is formed in the accommodation chamber. For example, the protruding body is configured to lock the accommodation target that has been accommodated in the accommodation chamber in the chamber, or to hold a cover member that closes the insertion port. The protruding body protrudes from an inner wall surface of the cylindrical body at a position spaced from the closing wall body toward the insertion port side. Meanwhile, the accommodating member is molded with a mold using an insulating material such as a synthetic resin. As the mold, for example, one to form the main shape of the accommodating member, one (a protruding body mold) to form an end of the protruding body on the closing wall body side, and the like are prepared. In this accommodating member, the cylinder-axis direction is set as a mold removal direction of these molds. Accordingly, a removal hole for the protruding body mold is required for the closing wall body in the accommodating member, and the removal hole remains as a through-hole after molding. The through-hole serves as an infiltration port of a liquid (water or the like), dust, or the like into the accommodation chamber, or causes a leakage of a liquid filler injected into the accommodation chamber.

### SUMMARY OF THE INVENTION

An object of the present invention is to provide an accommodation box and an electronic component unit which can form a protruding body without forming a mold removal hole open to an accommodation chamber.

In order to solve the above mentioned problem and achieve the object, an accommodation box according to one aspect of the present invention includes an accommodating member in which an accommodation target is accommodated, wherein the accommodating member includes: a cylindrical body having an inner space that serves as an accommodation chamber of the accommodation target; a closing wall body that closes one of both ends which is arranged to oppose in a cylinder-axis direction of the cylindrical body; and an insertion port which is open at another end and inserts the accommodation target, the cylindrical body has a double-wall structure, which includes an inner wall body having an inner wall surface forming the accommodation chamber and an outer wall body arranged to oppose an outer wall surface of the inner wall body with a gap therebetween, at least at one location, the outer wall body includes: a protruding wall portion protruding toward a side of the insertion port from the inner wall body; and at least one protruding body protruding from an inner wall surface of the protruding wall portion toward a side of the accommodation chamber within a range of a size of the gap, the double-wall structure has a space, which extends in the cylinder-axis direction in a state of providing the gap and has only both ends in the cylinder-axis direction opened, between the inner wall body and the outer wall body, and the space includes: a first opening on the side of the insertion port which is arranged to oppose the protruding body in the cylinder-axis direction; and a second opening on a side of the closing wall body which is arranged to oppose the protruding body in the cylinder-axis direction.

According to another aspect of the present invention, in the accommodation box, it is preferable that each of an end of the inner wall body on the side of the insertion port and an end of the protruding body on the side of the closing wall body is used as a locking portion to lock the accommodation target in the cylinder-axis direction.

According to still another aspect of the present invention, in the accommodation box, it is preferable that each of an end of the inner wall body on the side of the insertion port and an end of the protruding body on the side of the closing wall body is used as a locking portion to lock an electronic circuit board serving as the accommodation target in the cylinder-axis direction.

In order to achieve the object, an electronic component unit according to still another aspect of the present invention includes an electronic component or an electronic circuit board on which the electronic component is mounted which serves as an accommodation target; and an accommodating member in which the accommodation target is accommodated, wherein the accommodating member includes: a cylindrical body having an inner space that serves as an accommodation chamber of the accommodation target; a closing wall body that closes one of both ends which is arranged to oppose in a cylinder-axis direction of the cylindrical body; and an insertion port of the accommodation target which is open at another end, the cylindrical body has a double-wall structure, which includes an inner wall body having an inner wall surface forming the accommodation chamber and an outer wall body arranged to oppose an outer wall surface of the inner wall body with a gap therebetween, at least at one location, the outer wall body includes: a protruding wall portion protruding toward a side of the insertion port from the inner wall body; and at least one protruding body protruding from an inner wall surface of the protruding wall portion toward a side of the accommodation chamber within a range of a size of the gap, the double-wall structure has a space, which extends in the cylinder-axis direction in a state of providing the gap and has only both ends in the cylinder-axis direction opened, between the inner wall body and the outer wall body, and the space includes: a first opening on the side of the insertion port which is arranged to oppose the protruding body in the cylinder-axis direction; and a second opening on a side of the closing wall body which is arranged to oppose the protruding body in the cylinder-axis direction.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is an exploded perspective view illustrating an accommodation box and an electronic component unit according to an embodiment;

FIG. 2 is a perspective view illustrating the accommodation box and the electronic component unit according to the embodiment;

FIG. 3 is a perspective view illustrating an accommodating member;

FIG. 4 is a perspective view of the accommodating member as viewed from another angle;

FIG. 5 is a perspective view of the accommodating member as viewed from a closing wall body side;

FIG. 6 is a plan view of the accommodating member as viewed from an insertion port side;

FIG. 7 is a partially enlarged view of a section taken along a line X1-X1 of FIG. 6;

FIG. 8 is a partially enlarged view of a section taken along a line X2-X2 of FIG. 6;

FIG. 9 is a partially enlarged view of a section taken along a line X3-X3 of FIG. 6;

FIG. 10 is a cross-sectional view taken along a line Y-Y of FIG. 6;

FIG. 11 is a perspective view illustrating an electronic circuit board before bending;

FIG. 12 is a perspective view of the electronic circuit board before bending as viewed from another angle;

FIG. 13 is a front view illustrating the electronic circuit board before bending;

FIG. 14 is a perspective view illustrating an accommodating state of the electronic circuit board in an accommodation chamber, and illustrates a state before injection of a filler;

FIG. 15 is a perspective view illustrating the accommodating state of the electronic circuit board in the accommodation chamber, and illustrates a state after injection of the filler;

FIG. 16 is a plan view of the accommodating member accommodating the electronic circuit board as viewed from the insertion port side;

FIG. 17 is a partially enlarged view of a section taken along a line X1-X1 of FIG. 16;

FIG. 18 is a partially enlarged view of a section taken along a line X2-X2 of FIG. 16;

FIG. 19 is a partially enlarged view of a section taken along a line X3-X3 of FIG. 16; and

FIG. 20 is a cross-sectional view taken along a line Y-Y of FIG. 16.

### DETAILED DESCRIPTION OF THE PREFERRED EMBODIMENTS

Hereinafter, embodiments of an accommodation box and an electronic component unit according to the present invention will be described in detail with reference to the drawings. Incidentally, the invention is not limited by the embodiments.

### Embodiment

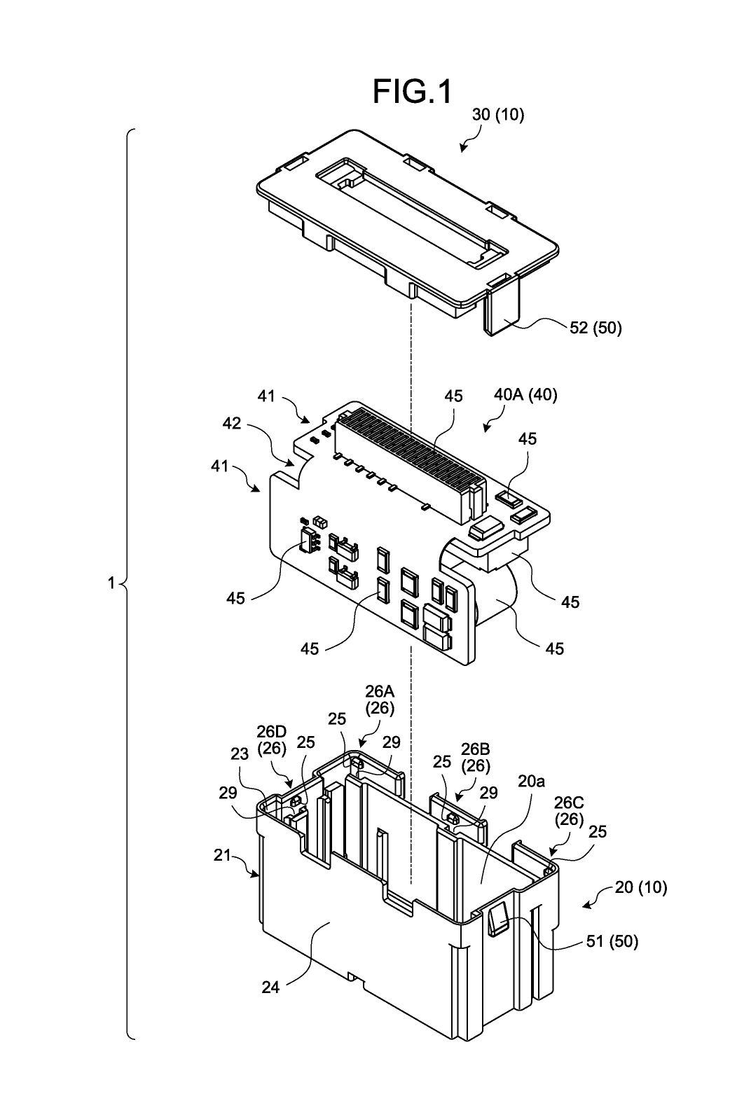

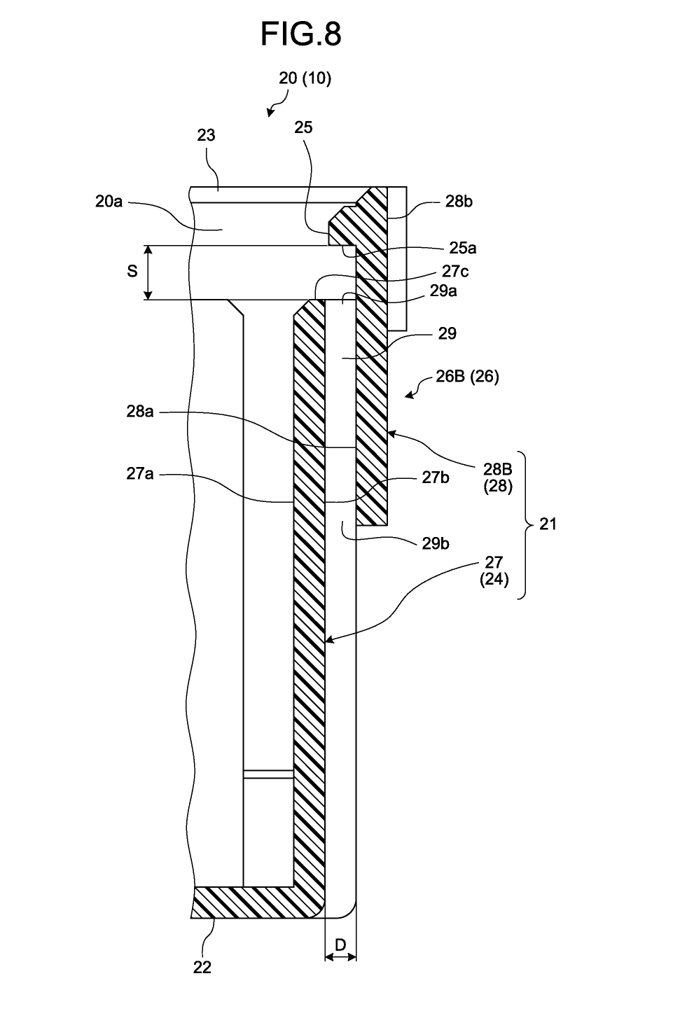

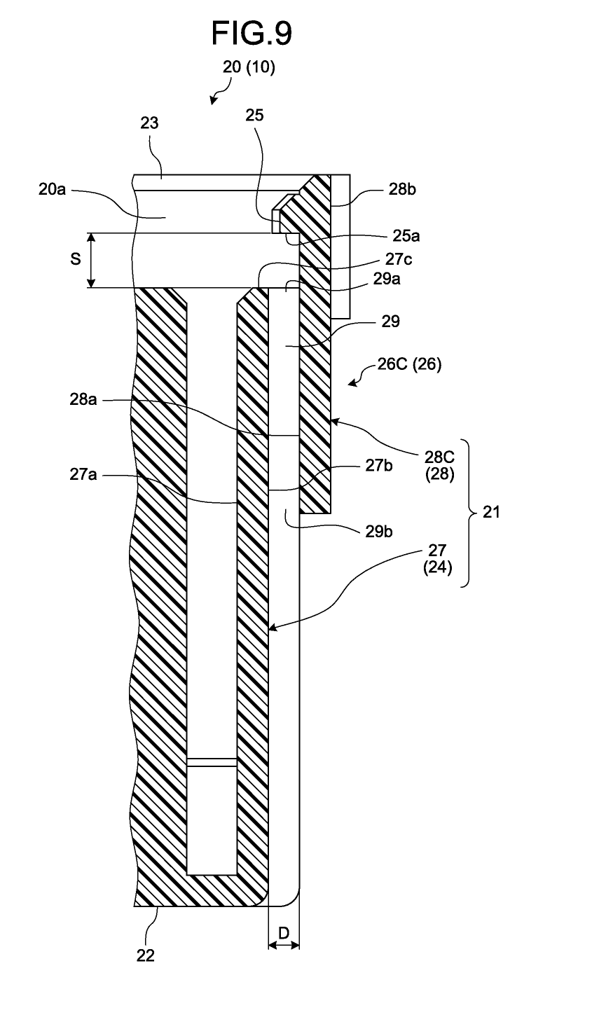

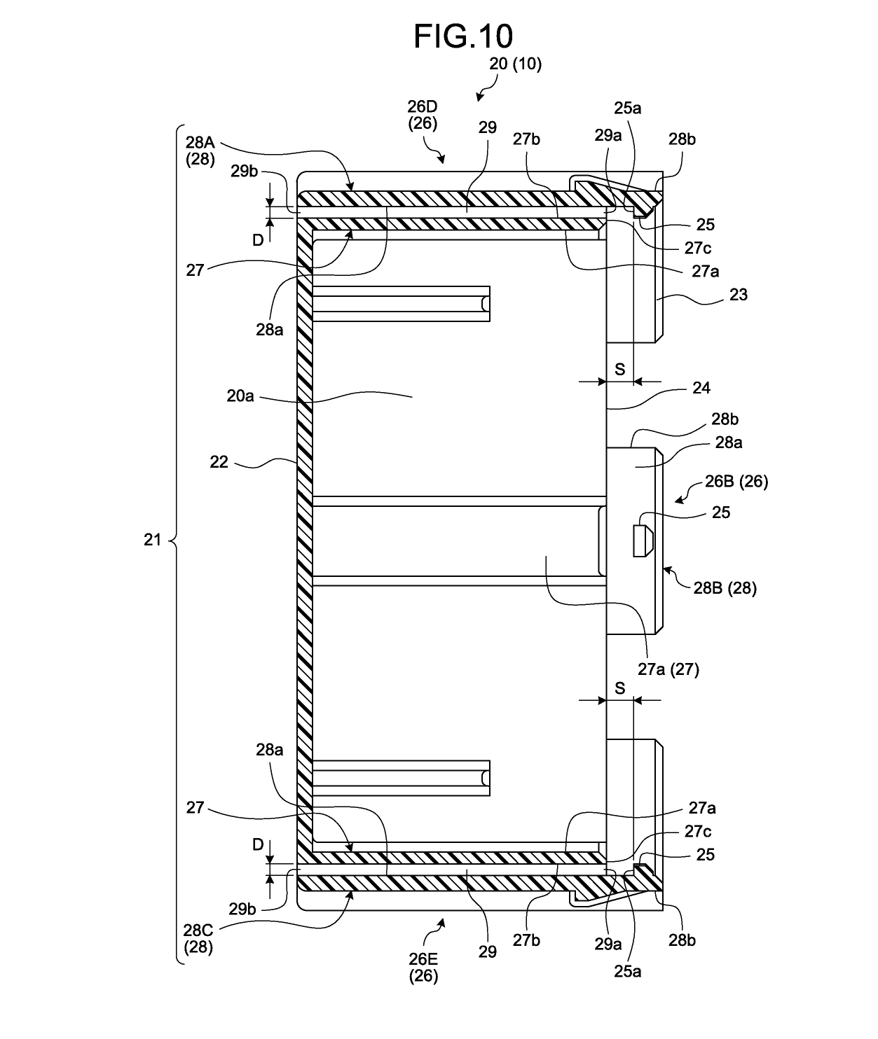

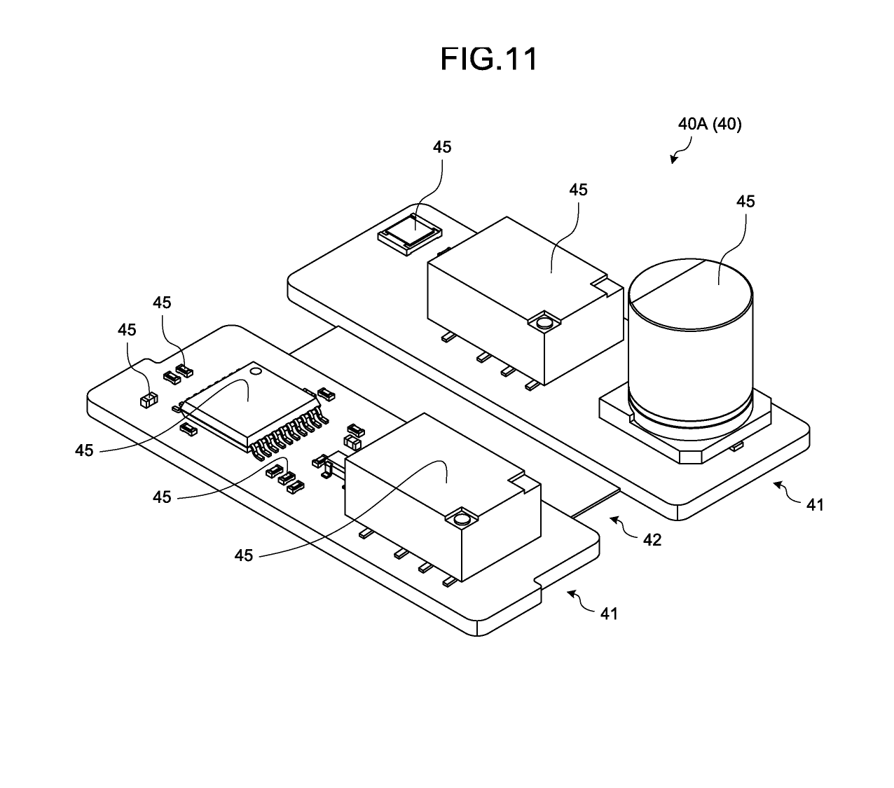

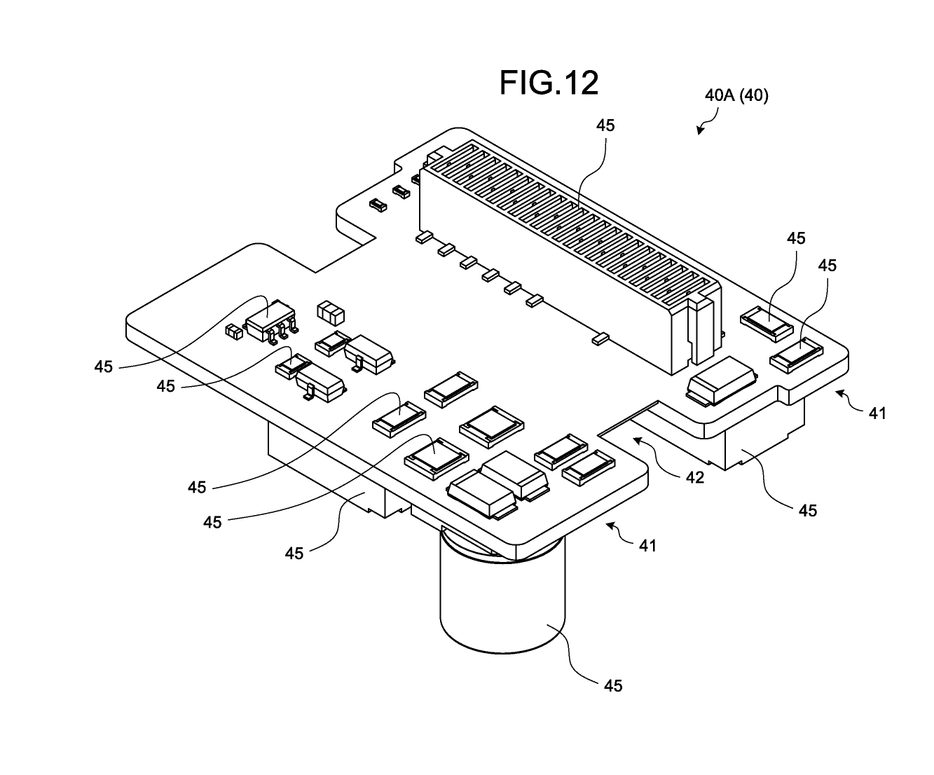

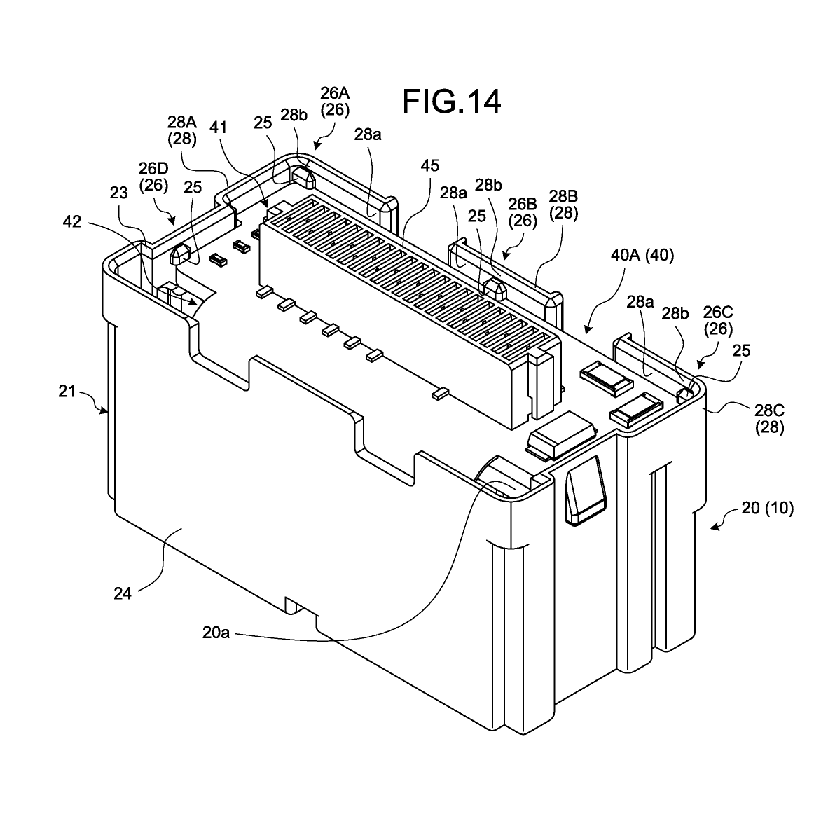

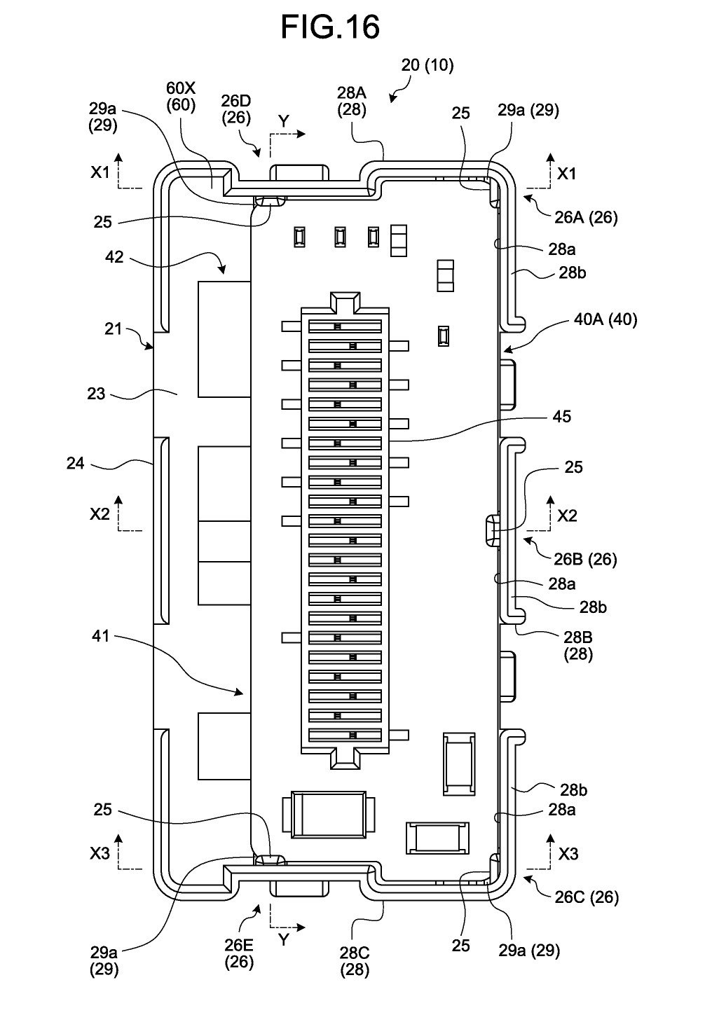

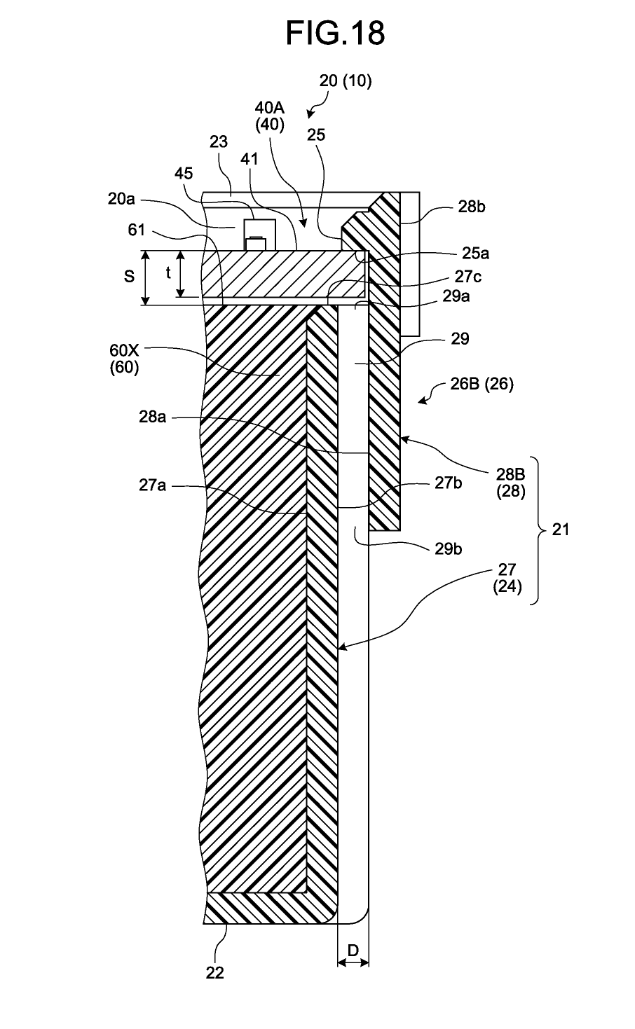

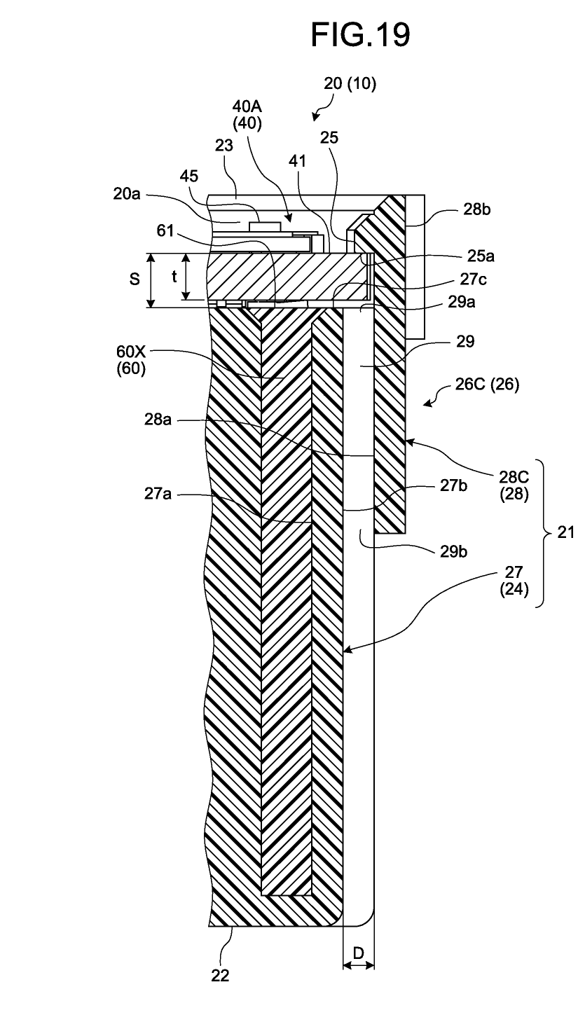

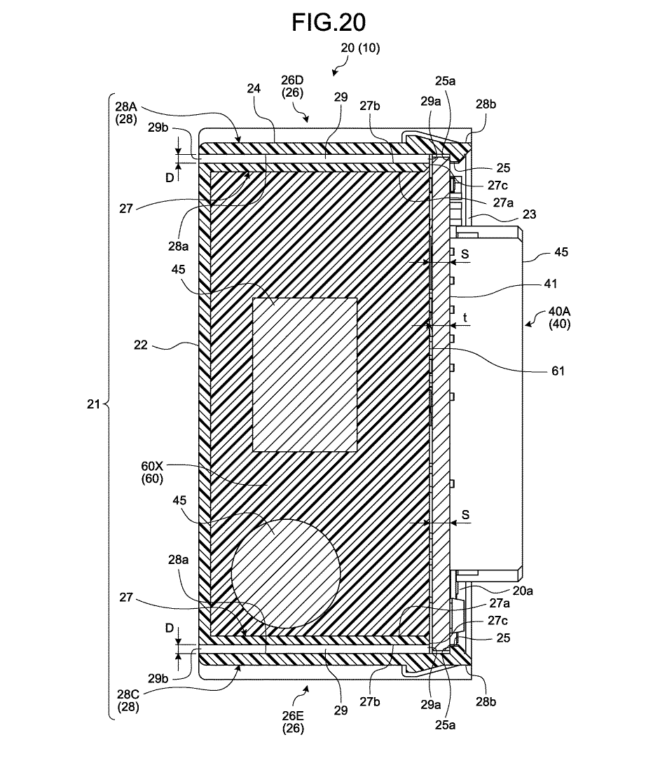

One of embodiments of the accommodation box and the electronic component unit according to the present invention will be described with reference to FIGS. 1 to 20.

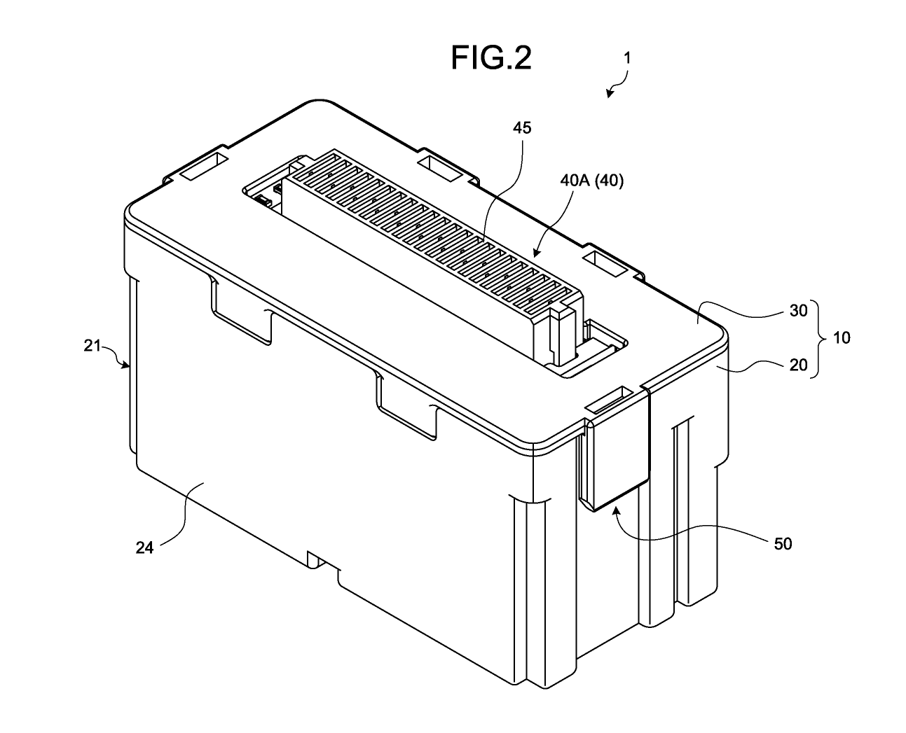

In FIGS. 1 and 2, reference numeral 1 represents the electronic component unit according to the present embodiment. In addition, reference numeral 10 in the same drawings represents the accommodation box of the present embodiment.

The electronic component unit 1 of the present embodiment includes the accommodation box 10 as a housing. The accommodation box 10 is configured as a structural body in which a plurality of housing members is assembled. The accommodation box 10 in this example is constituted by an accommodating member 20 and a cover member 30 (FIGS. 1 and 2). In addition, the electronic component unit 1 of the present embodiment includes an accommodation target 40 to be accommodated in the accommodation box 10 (FIGS. 1 and 2). As the accommodation target 40, an electronic component or an electronic circuit board on which the electronic component is mounted, or the like can be considered.

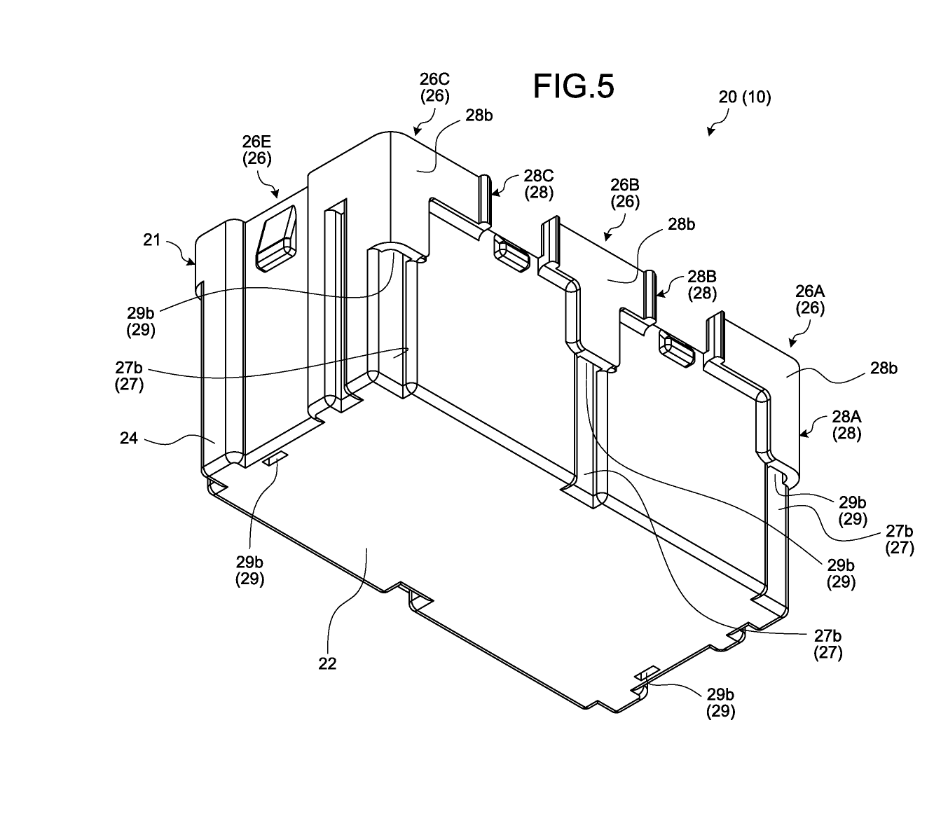

The accommodation box 10 is molded using an insulating material such as synthetic resin. In the accommodation box 10 of the present embodiment, the accommodation target 40 is accommodated in the accommodating member 20. For example, the accommodating member 20 includes: a cylindrical body 21 having an inner space that serves as an accommodation chamber 20a of an accommodation target 40 (FIGS. 1, 3, 4, and 6 to 10); a closing wall body 22 that closes one of both ends arranged to oppose each other in a cylinder-axis direction of the cylindrical body 21 (FIGS. 5 to 10); and an insertion port 23 of the accommodation target 40 which is open at the other end (FIGS. 1, 3, 4, and 6 to 10).

The accommodating member 20 is molded with a mold using an insulating material such as a synthetic resin. In the accommodating member 20, the cylinder-axis direction of the cylindrical body 21 is set as a mold removal direction of the mold.

The cylindrical body 21 includes a tubular main wall body 24 erected from a peripheral edge of the closing wall body 22 toward the insertion port 23 (FIGS. 1 to 10). In this example, the closing wall body 22 is formed in a rectangular shape, and the main wall body 24 is formed in a rectangular tube shape. Accordingly, the accommodating member 20 in this example is molded as a rectangular tubular box whose one end is closed by the closing wall body 22, has the rectangular parallelepiped accommodation chamber 20a formed therein, and has the insertion port 23 formed at the other end. The cover member 30 is a member that closes the insertion port 23, and is molded in a rectangular shape using an insulating material such as a synthetic resin.

The accommodating member 20 of the present embodiment has at least one protruding body 25 protruding toward the accommodation chamber 20a (FIGS. 1, 3, 4, 6 to 10). For example, the protruding body 25 may be provided to lock the accommodation target 40 accommodated in the accommodation chamber 20a in the chamber, or may be provided to hold the cover member 30. In the accommodation box 10 in this example, the cover member 30 is held by the accommodating member 20 outside the accommodation chamber 20a. That is, in the accommodation box 10 in this example, the cover member 30 is held by the accommodating member 20 using a holding structure 50 (FIGS. 1 and 2) that engages a claw-shaped first engaging portion 51 provided on an outer wall surface side of the accommodating member 20 with a claw-shaped second engaging portion 52 provided on the cover member 30. Meanwhile, the accommodation target 40 accommodated in the accommodation chamber 20a is locked in the chamber in the accommodation box 10 in this example. Accordingly, the protruding body 25 is provided so as to lock the accommodation target 40 in the accommodation chamber 20a although will be described in detail later.

At least an electronic circuit board 40A is accommodated in the accommodation chamber 20a in this example as the accommodation target 40 (FIGS. 1 and 2). The electronic circuit board 40A illustrated herein is a so-called printed circuit board (PCB) in which an electronic component 45 is mounted on a so-called printed wiring board (PWB).

The electronic circuit board 40A includes a plurality of hard rigid board portions 41 and at least one soft flexible board portion 42 which are integrated (FIGS. 1 and 11 to 16). The electronic component 45 to be mounted is mounted on the electronic circuit board 40A (FIGS. 1, 2, and 11 to 16).

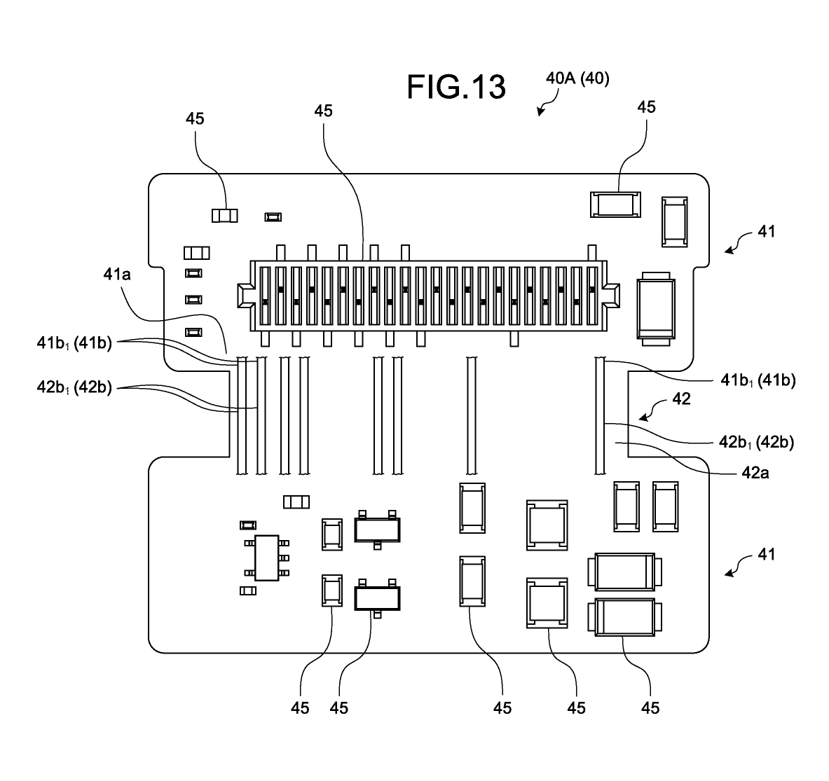

The rigid board portion 41 has an insulating insulator 41a and a conductive circuit pattern 41b arranged in layers (FIG. 13).

The insulator 41a is made of an insulating material. The insulator 41a in this example is further divided into a plurality of layers. For example, the insulator 41a includes one hard core layer and a plurality of prepreg layers that is softer than the core layer although not illustrated. The core layer is formed of an insulating material, for example, an epoxy resin, a glass epoxy resin, a paper epoxy resin, ceramics, or the like. On the other hand, the prepreg layer is formed by uniformly impregnating a thermosetting resin (such as epoxy mixed with an additive such as a curing agent) into a fibrous reinforcing material (such as glass cloth and a carbon fiber), and then, turning the resultant into a semi-cured state by heating or drying. Therefore, the prepreg layer is softer than the core layer and has flexibility.

The circuit pattern 41b is formed using a conductive material, for example, by etching processing or the like. The circuit pattern 41b in this example is formed using a copper foil (particularly, a rolled copper foil having better flexibility than an electrolytic copper foil). The circuit pattern 41b is obtained by stretching a plurality of conductive portions 41b₁ (FIG. 13), and the electronic components 45 corresponding to the conductive portions 41b₁, respectively, are electrically connected thereto. Incidentally, the circuit pattern 41b in this drawing illustrates only some of the conductive portions 41b₁ for convenience of illustration.

In the rigid board portion 41, for example, the circuit pattern 41b is arranged on each plane of the core layer, and the prepreg layer on the inner layer side is stacked on both the planes so as to cover the circuit pattern 41b and a plane of the core layer where the circuit pattern 41b is not arranged. Further, in the rigid board portion 41, another circuit patterns 41b is arranged on each of planes opposite to the core layer side of the prepreg layer on the inner layer side, and another prepreg layer on the outer layer side is stacked on both the planes so as to cover the circuit pattern 41b and a plane of the prepreg layer where the circuit pattern 41b is not arranged. In addition, in the rigid board portion 41, still another circuit pattern 41b is further arranged on each of planes opposite to the core layer side of the prepreg layer on the outer layer side. In this manner, the rigid board portion 41 has a multilayer structure formed of the insulator 41a including the plurality of layers (the core layer and the prepreg layers) and the plurality of circuit patterns 41b divided for each layer. In the rigid board portion 41, the electronic components 45 corresponding to the respective circuit patterns 41b are electrically connected to the circuit patterns 41b as the plurality of electronic components 45 are mounted on both the planes thereof.

Here, the electronic components 45 in this example are mounted on each plane of the rigid board portion 41. The electronic component 45 referred to herein indicates, for example, a circuit protection part such as a relay and a fuse, a capacitor, a resistor, a transistor, an intelligent power switch (IPS), a connector, a terminal fitting, an electronic control unit (so-called electronic control unit (ECU)), various sensor elements, a light emitting diode (LED) element, a speaker, and the like.

The flexible board portion 42 has an insulating insulator 42a and a conductive circuit pattern 42b arranged in layers (FIG. 13).

The insulator 42a is softer than the insulator 41a of the rigid board portion 41 and has flexibility. Accordingly, the insulator 42a is formed using an insulating material which is softer than the insulator 41a of the rigid board portion 41.

The circuit pattern 42b is formed using a conductive material, for example, by etching processing or the like. The circuit pattern 42b in this example is formed using a copper foil (particularly, a rolled copper foil having better flexibility than an electrolytic copper foil). In the circuit pattern 42b, a plurality of conductive portions 42b₁ are stretched (FIG. 13). The circuit pattern 42b in this example is electrically connected to each of the circuit patterns 41b on at least two of the plurality of rigid board portions 41. In the circuit pattern 42b, the respective conductive portions 42b₁ are electrically connected to the conductive portions 41b₁ of the respective circuit patterns 41b of the two rigid board portions 41. That is, the circuit pattern 42b in this example serves as a connection conductor that electrically connects the circuit pattern 41b of one rigid board portion 41 with the circuit pattern 41b of the other rigid board portion 41.

Since the circuit pattern 42b is formed using the rolled copper foil excellent in flexibility in the flexible board portion 42, the flexibility increases as a ratio of the circuit pattern 42b to the total area as viewed in a stacking direction (that is, as a ratio of the copper foil increases). In other words, the flexibility increases as a ratio of the insulator 42a to the total area as viewed in the stacking direction decreases in the flexible board portion 42.

The electronic circuit board 40A is bent in an L-shape with the flexible board portion 42 as a boundary and is accommodated in an accommodation chamber 20a of an accommodating member 20 in the bent state (FIGS. 1 and 14 to 16).

As described above, the electronic circuit board 40A is locked in the accommodation chamber 20a using the protruding body 25 of the accommodation chamber 20a in the accommodating member 20. Therefore, the protruding body 25 will be described in detail hereinafter.

The cylindrical body 21 forming the accommodating member 20 has a double-wall structure 26 at least at one place (FIGS. 1, 3 to 10, and 14 to 20). In this example, the double-wall structure 26 is provided at least on the insertion port 23 side.

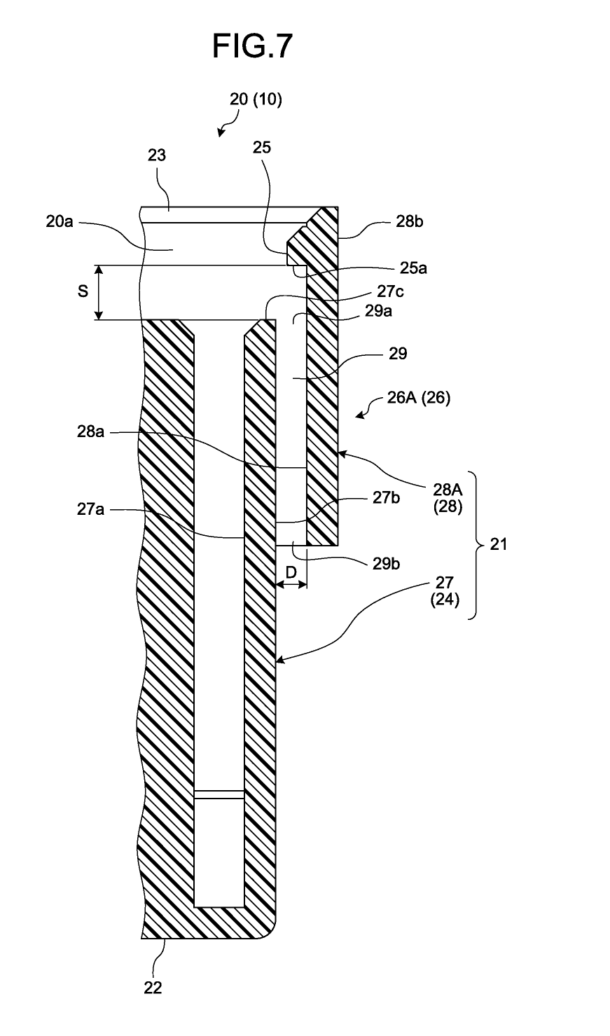

The double-wall structure 26 includes an inner wall body 27 having an inner wall surface 27a forming the accommodation chamber 20a and an outer wall body 28 arranged to oppose an outer wall surface 27b of the inner wall body 27 with a gap D therebetween (FIGS. 7 to 10 and 17 to 20).

The inner wall body 27 in this example indicates a part of the main wall body 24.

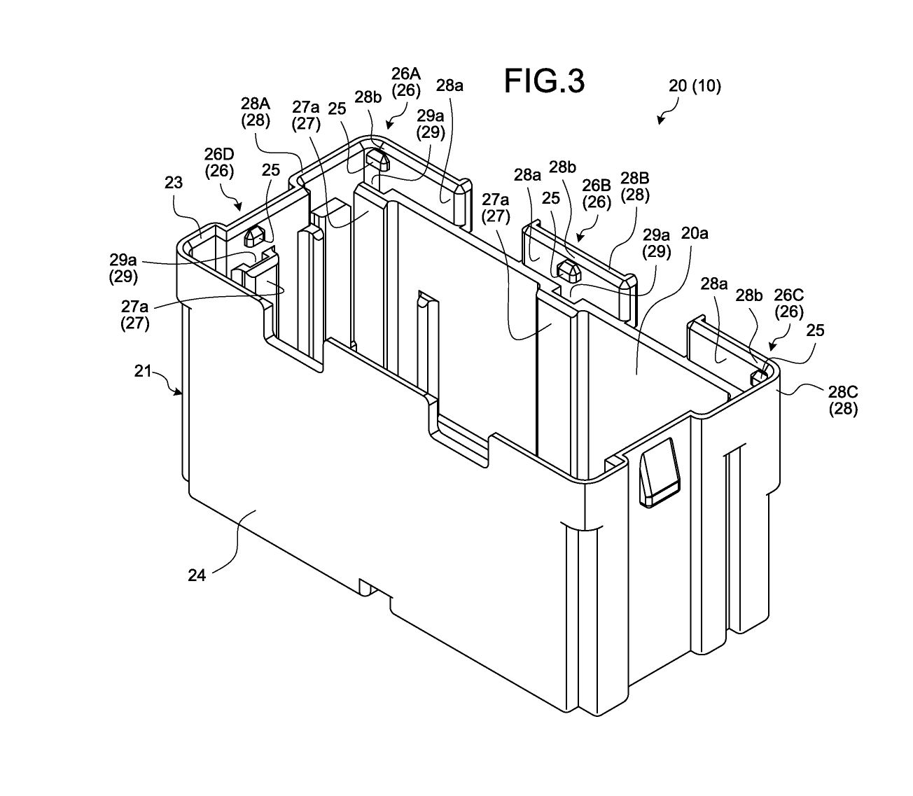

The outer wall body 28 has an inner wall surface 28a arranged to oppose the outer wall surface 27b of the inner wall body 27 with the gap D therebetween (FIGS. 7 to 10 and 17 to 20). Further, the outer wall body 28 has a protruding wall portion 28b protruding toward the insertion port 23 side from the inner wall body 27 (FIGS. 3 to 10 and 14 to 20). In the outer wall body 28, the inner wall surface 28a is extended at least up to the protruding wall portion 28b. In addition, the outer wall body 28 has at least one protruding body 25 protruding from the inner wall surface 28a of the protruding wall portion 28b toward the accommodation chamber 20a within a range of a size of the gap D (FIGS. 1, 3, 4, 6 to 10, and 14 to 20). That is, the protruding body 25 is provided such that an end 25a on the closing wall body 22 side is not arranged to oppose an end 27c on the insertion port 23 side of the inner wall body 27 in the cylinder-axis direction of the cylindrical body 21 (FIGS. 7 to 10 and 17 to 20).

The protruding body 25 is arranged with an interval S on the insertion port 23 side of the end 27c of the inner wall body 27 (FIGS. 7 to 10 and 17 to 20). Each of the end 25a of the protruding body 25 and the end 27c of the inner wall body 27 is used as a locking portion to lock the accommodation target 40 in the cylinder-axis direction of the cylindrical body 21. In this example, the insulator 41a of one of the rigid board portions 41 is inserted between the end 25a of the protruding body 25 and the end 27c of the inner wall body 27 so that the insulator 41a is locked by the respective ends 25a and 27c. That is, each of the end 25a of the protruding body 25 and the end 27c of the inner wall body 27 is used as the locking portion to lock the electronic circuit board 40A (the insulator 41a of the one rigid board portion 41) in the cylinder-axis direction of the cylindrical body 21. Therefore, the interval S is set to at least a size equal to or larger than a plate thickness t of the insulator 41a.

In this example, the insulator 41a is inserted between the end 25a of the protruding body 25 and the end 27c of the inner wall body 27 together with accommodation of the electronic circuit board 40A in the accommodation chamber 20a. Here, flexibility is imparted at least on the protruding wall portion 28b of the outer wall body 28 in order to enhance the workability of inserting the insulator 41a and the durability of the accommodating member 20.

Further, the double-wall structure 26 has a space 29, which extends in the cylinder-axis direction of the cylindrical body 21 in the state of providing the gap D and has only both ends in the cylinder-axis direction opened, between the inner wall body 27 and the outer wall body 28 (FIGS. 1, 3 to 10, and 16 to 20). The space 29 is formed using a mold (protruding body mold) for shaping the end 25a of the protruding body 25 and appears when the protruding body mold is withdrawn. That is, it is possible to form the protruding body 25 in the accommodating member 20 without forming a removal hole of the protruding body mold open to the accommodation chamber 20a as in the related art. The space 29 has a first opening 29a (FIGS. 3, 4, 6 to 10, and 16 to 20) on the insertion port 23 side which is arranged to oppose the protruding body 25 in the cylinder-axis direction and a second opening 29b (FIGS. 5, 7 to 10, and 17 to 20) on the closing wall body 22 side which is arranged to oppose the protruding body 25 in the cylinder-axis direction.

Here, the space 29 allows the first opening 29a to communicate with the accommodation chamber 20a, but does not allow the other portion to communicate with the accommodation chamber 20a. Therefore, even if the protruding body 25 is provided in the accommodation chamber 20a, the accommodating member 20 can suppress infiltration of a liquid (water or the like), dust, or the like into the accommodation chamber 20a.

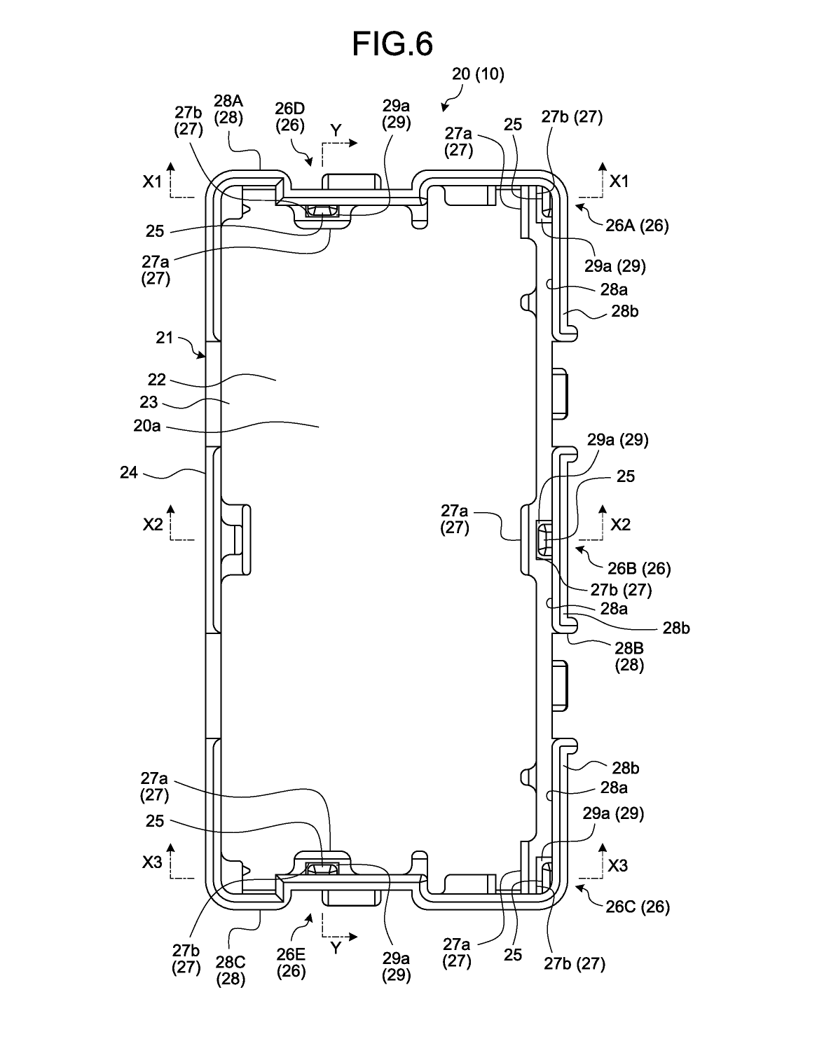

In this example, the double-wall structure 26 is provided at five locations (first to fifth double-wall structures 26A to 26E) as illustrated in FIG. 6. Each of the first to fifth double-wall structures 26A to 26E has the space 29.

The inner wall body 27 in this example is provided for each of the first to fifth double-wall structures 26A to 26E.

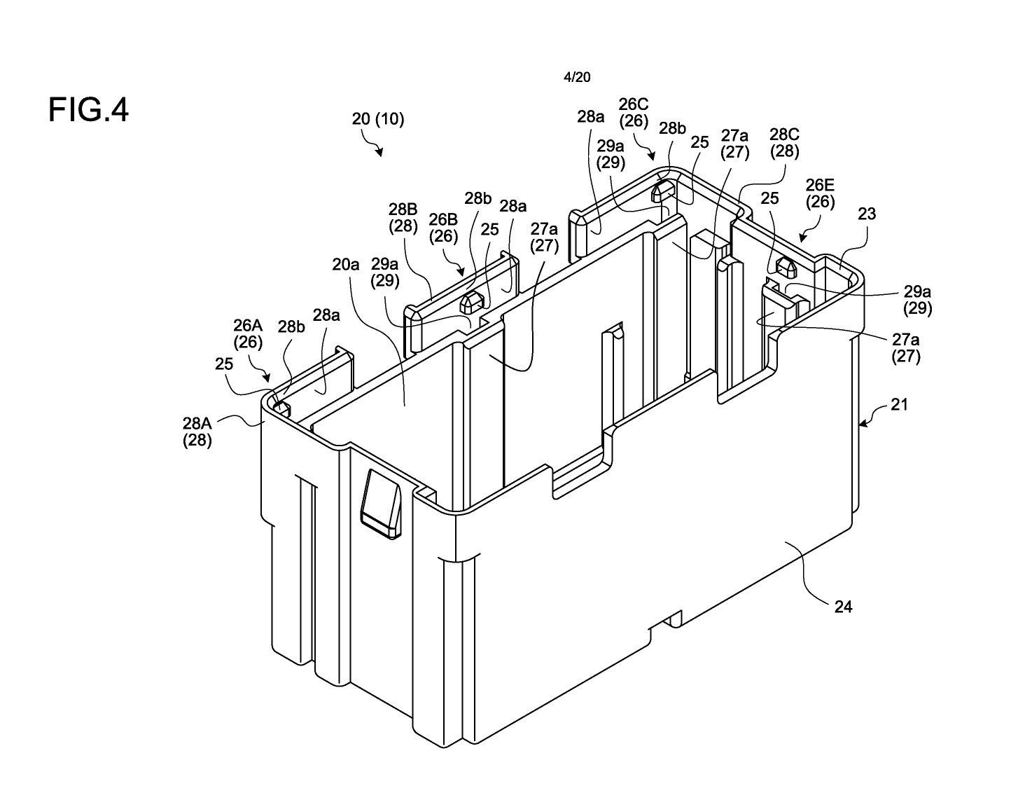

On the other hand, the outer wall body 28 may be provided for each of the first to fifth double-wall structures 26A to 26E, or may be shared among a plurality of double-wall structures out of the first to fifth double-wall structures 26A to 26E. The cylindrical body 21 in this example includes first to third outer wall bodies 28A to 28C (FIGS. 3 to 6 and 14 to 16). Each of the first to third outer wall bodies 28A to 28C has the inner wall surface 28a and the protruding wall portion 28b. The first outer wall body 28A is shared between the first double-wall structure 26A and the fourth double-wall structure 26D, and has the protruding body 25 corresponding to each of the first double-wall structure 26A and the fourth double-wall structure 26D on the inner wall surface 28a of the protruding wall portion 28b (FIGS. 3, 6, and 14 to 16). The second outer wall body 28B is provided solely for the second double-wall structure 26B, and has the protruding body 25 corresponding to the second double-wall structure 26B on the inner wall surface 28a of the protruding wall portion 28b (FIGS. 3, 4, 6, and 14 to 16). The third outer wall body 28C is shared between the third double-wall structure 26C and the fifth double-wall structure 26E, and has the protruding body 25 corresponding to each of the third double-wall structure 26C and the fifth double-wall structure 26E on the inner wall surface 28a of the protruding wall portion 28b (FIGS. 4, 6, and 16). Since the space 29 is provided for each of the protruding bodies 25 in the accommodating member 20 in this example, it is possible to form all the protruding bodies 25 without forming the removal hole of the protruding body mold as in the related art.

As described above, the space 29 is formed in accordance with withdrawal of the protruding body mold after forming the end 25a of the protruding body 25 on the closing wall body 22 side using the protruding body mold in the accommodating member 20 of the present embodiment. However, the space 29 is not a through-hole directly open to the accommodation chamber 20a. That is, it is possible to form the protruding body 25 in the accommodating member 20 of the present embodiment without forming the through-hole (removal hole for the protruding body mold) directly open to the accommodation chamber 20a. Therefore, the accommodation box 10 and the electronic component unit 1 of the present embodiment can suppress the infiltration of a liquid (water or the like), dust, and the like into the accommodation chamber 20a from the space 29.

Further, since the end 27c of the inner wall body 27 of the double-wall structure 26 is used as the locking portion of the accommodation target 40 in the accommodating member 20 of the present embodiment, it is unnecessary to prepare the locking portion as a dedicated one for locking the accommodation target 40. Accordingly, the accommodating member 20 can suppress a size increase and suppress an increase in cost. Further, since each of the end 25a of the protruding body 25 and the end 27c of the inner wall body 27 is used as the locking portion of the accommodation target 40 in the accommodating member 20 of the present embodiment, the accommodation target 40 can be accommodated along the inner wall surface 28a of the outer wall body 28 of the double-wall structure 26. Accordingly, the accommodating member 20 can also suppress the size increase from this point of view. As described above, the accommodation box 10 and the electronic component unit 1 of the present embodiment can suppress the size increase and the increase in cost.

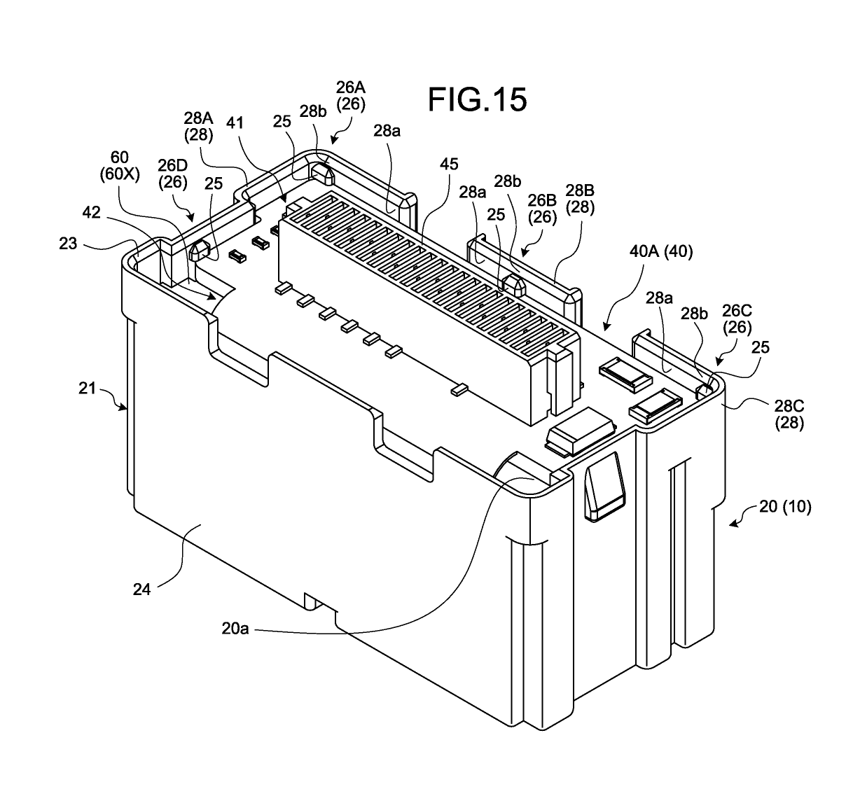

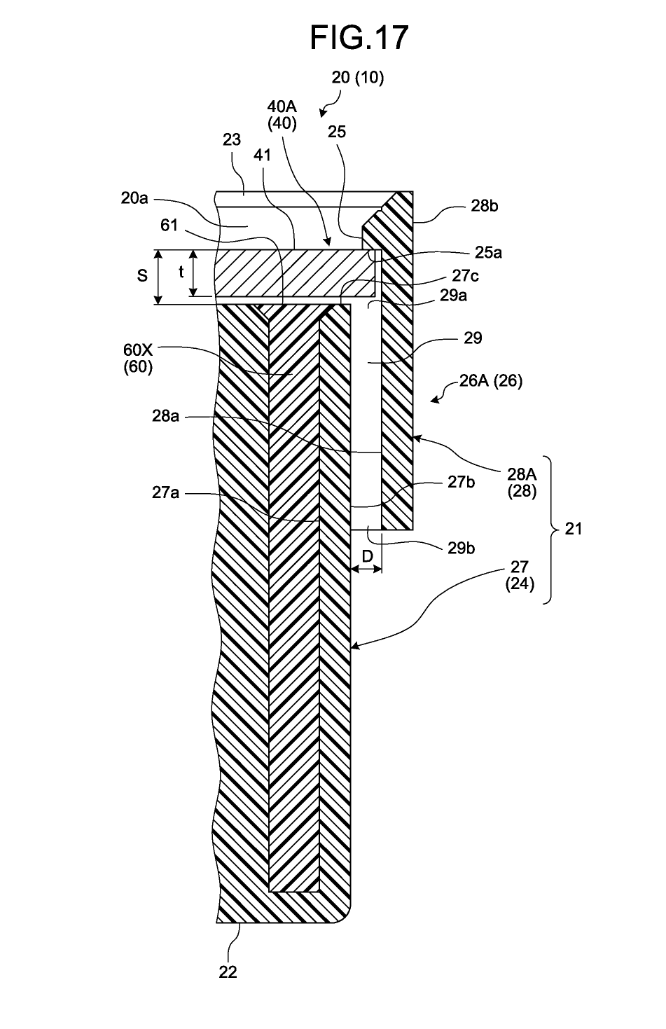

Meanwhile, a sealing body 60 is formed in the accommodation chamber 20a by filling the accommodation chamber 20a accommodating the electronic circuit board 40A with a filler 60X in the electronic component unit 1 of the present embodiment (FIGS. 15 to 20). The electronic component unit 1 can improve an insulating property, moisture-proofness, strength, or the like of the electronic circuit board 40A by covering the electronic circuit board 40A with the sealing body 60. For example, a liquid material such as a thermosetting resin that can be cured after filling is used as the filler 60X. Here, when the filler 60X is injected into the accommodation chamber 20a, it is desirable to prevent the filler 60X from entering the space 29 through the first opening 29a. Therefore, it is desirable to arrange the first opening 29a to be closer to the insertion port 23 side than a liquid surface 61 on the insertion port 23 side of the liquid filler 60X injected into the accommodation chamber 20a or at the same position as the liquid surface 61 (FIGS. 17 to 20). In this example, the end 27c on the insertion port 23 side of the inner wall body 27 is present at the same position as the first opening 29a of the space 29 in the cylinder-axis direction of the cylindrical body 21. Accordingly, here, the end 27c of the inner wall body 27 is arranged to be closer to the insertion port 23 side than the liquid surface 61 of the filler 60X or at the same position as the liquid surface 61. As a result, the accommodation box 10 and the electronic component unit 1 of the present embodiment can prevent a leakage of the liquid filler 60X through the space 29.

In an accommodating member of the accommodation box and the electronic component unit according to the present embodiment, a space is formed in accordance with withdrawal of the protruding body mold after forming an end of the protruding body on a closing wall body side using the protruding body mold. However, this space is not a through-hole directly open to the accommodation chamber. That is, it is possible to form the protruding body in the accommodating member without forming the through-hole (removal hole for the protruding body mold) directly open to the accommodation chamber. Therefore, the accommodation box and the electronic component unit according to the present embodiment can suppress infiltration of a liquid (water or the like), dust, or the like into the accommodation chamber from the space.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An accommodation box comprising:
an accommodating member in which an accommodation target is accommodated, wherein
the accommodating member includes: a cylindrical body having an inner space that serves as an accommodation chamber of the accommodation target; a closing wall body that closes one of both ends which is arranged to oppose in a cylinder-axis direction of the cylindrical body; and an insertion port which is open at another end and inserts the accommodation target,
the cylindrical body has a double-wall structure, which includes an inner wall body having an inner wall surface forming the accommodation chamber and an outer wall body arranged to oppose an outer wall surface of the inner wall body with a gap therebetween, at least at one location,
the outer wall body includes: a protruding wall portion protruding toward a side of the insertion port from the inner wall body; and at least one protruding body protruding from an inner wall surface of the protruding wall portion toward a side of the accommodation chamber within a range of a size of the gap,
the double-wall structure has a space, which extends in the cylinder-axis direction in a state of providing the gap and has only both ends in the cylinder-axis direction opened, between the inner wall body and the outer wall body, and
the space includes: a first opening on the side of the insertion port which is arranged to oppose the protruding body in the cylinder-axis direction; and a second opening on a side of the closing wall body which is arranged to oppose the protruding body in the cylinder-axis direction.

2. The accommodation box according to claim 1, wherein
each of an end of the inner wall body on the side of the insertion port and an end of the protruding body on the side of the closing wall body is used as a locking portion to lock the accommodation target in the cylinder-axis direction.

3. The accommodation box according to claim 1, wherein
each of an end of the inner wall body on the side of the insertion port and an end of the protruding body on the side of the closing wall body is used as a locking portion to lock an electronic circuit board serving as the accommodation target in the cylinder-axis direction.

4. An electronic component unit comprising:
an electronic component or an electronic circuit board on which the electronic component is mounted which serves as an accommodation target; and
an accommodating member in which the accommodation target is accommodated, wherein
the accommodating member includes: a cylindrical body having an inner space that serves as an accommodation chamber of the accommodation target; a closing wall body that closes one of both ends which is arranged to oppose in a cylinder-axis direction of the cylindrical body; and an insertion port of the accommodation target which is open at another end,
the cylindrical body has a double-wall structure, which includes an inner wall body having an inner wall surface forming the accommodation chamber and an outer wall body arranged to oppose an outer wall surface of the inner wall body with a gap therebetween, at least at one location,
the outer wall body includes: a protruding wall portion protruding toward a side of the insertion port from the inner wall body; and at least one protruding body protruding from an inner wall surface of the protruding wall portion toward a side of the accommodation chamber within a range of a size of the gap,
the double-wall structure has a space, which extends in the cylinder-axis direction in a state of providing the gap and has only both ends in the cylinder-axis direction opened, between the inner wall body and the outer wall body, and
the space includes: a first opening on the side of the insertion port which is arranged to oppose the protruding body in the cylinder-axis direction; and a second opening on a side of the closing wall body which is arranged to oppose the protruding body in the cylinder-axis direction.
